(19) United States
(12) Patent Application Publication
(10) Pub. No.: US 2026/0123334 A1
(43) Pub. Date: Apr. 30, 2026

(54) BUFFER UNIT AND SUBSTRATE PROCESSING APPARATUS INCLUDING THE SAME

(71) Applicant: SEMES CO., LTD., Chungcheongnam-do (KR)

(72) Inventors: Joon Hee LEE, Suwon-si (KR); Ju Yeon CHO, Suwon-si (KR)

(21) Appl. No.: 19/366,633

(22) Filed: Oct. 23, 2025

(30) Foreign Application Priority Data
Oct. 25, 2024 (KR) 10-2024-0147853

(51) Int. Cl. H01L 21/67; B08B 5/02; B08B 5/04; B08B 17/02

(52) U.S. Cl. CPC H10P 72/0464; B08B 5/02; B08B 5/04; B08B 17/02; H10P 72/0456

(57) ABSTRACT

Provided is an apparatus for processing a substrate, the apparatus including: a process module for processing a substrate; a buffer unit having a buffer blade on which the substrate is placed; and transfer unit for transferring the substrate between the process module and the buffer unit, in which the buffer unit includes a moving member for moving the buffer blade so that the buffer blade is moved to a standby position and a use position where the transfer unit is accessible.

### CROSS-REFERENCE TO RELATED APPLICATION

This application claims priority to and the benefit of Korean Patent Application No. 10-2024-0147853 filed in the Korean Intellectual Property Office on Oct. 25, 2024, the entire contents of which are incorporated herein by reference.

### TECHNICAL FIELD

The present invention relates to a buffer unit, and a substrate processing apparatus including the same.

### BACKGROUND ART

In order to manufacture a semiconductor device, various processes, such as deposition, photolithography, etching, and cleaning, are performed. An apparatus performing some of these processes has a plurality of chambers. After the process is performed in one chamber, the substrate is transferred to another chamber.

According to an example, a substrate processing apparatus performing a photolithography process includes various chambers, such as an application chamber for applying a photosensitive solution, such as a photoresist, to a substrate, a bake chamber for heating or cooling the substrate before or after the photosensitive solution is applied, and an edge exposure chamber for exposing an edge region of the substrate. The substrate is transferred to these chambers in a preset order.

The substrate must be placed in a correct position on a unit supporting the substrate in the chamber. When the process is performed in a state in which the substrate is not placed in the correct position, process defects are likely to occur. For example, when the process of processing the edge region of the substrate is performed without alignment of the substrate, a specific chemical or rinse solution also unintentionally affects the center of the substrate, and thus the quality of the process result cannot meet the reference value. In some cases, the center and edge of the substrate exposed to the chemical or rinse solution may be damaged.

Therefore, the substrate must be aligned when the substrate is transferred while being out of the correct position on the transfer unit or when the substrate is transferred while being out of the correct position on the unit supporting the substrate in the chamber. However, since there is no function to align the substrate in the transfer unit, an alignment buffer for centering the substrate needs to be placed in the facility.

### SUMMARY OF THE INVENTION

The present invention has been made in an effort to provide an alignment buffer unit capable of shortening an alignment time by reducing a transfer section of a main transfer unit when aligning a substrate, and a substrate processing facility including the same.

The present invention has also been made in an effort to provide an alignment buffer unit that is easy to maintain and a substrate processing facility including the same.

The present invention has also been made in an effort to provide an alignment buffer unit having excellent particle shielding performance and a substrate processing facility including the same.

The objectives of the present disclosure are not limited thereto and other objectives not stated herein may be clearly understood by those skilled in the art from the following description.

An exemplary embodiment of the present disclosure, a substrate processing facility comprising: a process module for processing a substrate; a buffer unit having a buffer blade on which the substrate is placed; and a transfer unit for transferring the substrate between the process module and the buffer unit, wherein the buffer unit includes a moving member for moving the buffer blade so that the buffer blade is moved to a standby position and a use position where the transfer unit may be accessible.

According to the exemplary embodiment of the present invention, wherein the moving member may includes, a fixed mounting table on which the buffer blade is fixed; a movable mounting table on which the fixed mounting table is installed; and a horizontal driving unit for moving the movable mounting table in a horizontal direction.

According to the exemplary embodiment of the present invention, wherein the moving member further may includes a rotation member provided to allow the fixed mounting table to rotate on the movable mounting table.

According to the exemplary embodiment of the present invention, wherein the rotation member may includes: a hinge part including a rotary shaft connected to the fixed mounting table and a bearing installed on the rotary shaft and connected to the movable mounting table; and a rotation driving unit for rotating the hinge part.

According to the exemplary embodiment of the present invention, the substrate processing facility may further include a foreign substance removing unit connected to the bearing to remove foreign substances by performing air intake on the bearing.

According to the exemplary embodiment of the present invention, wherein the foreign substance removing unit may includes: an intake port installed on the bearing; and a suction line connected to the intake port.

According to the exemplary embodiment of the present invention, wherein the horizontal driving unit may includes: a ball spline rotatably connected by an actuator; and a bellows that is installed to surround the ball spline and is stretched in a longitudinal direction as the movable mounting table moves horizontally.

According to the exemplary embodiment of the present invention, wherein the buffer blade may be positioned in a transfer region where the transfer unit is located by a rotation operation of the rotation member.

According to the exemplary embodiment of the present invention, wherein the moving member may includes: a fixed mounting table on which the buffer blade is fixed; a movable mounting table on which the fixed mounting table is installed; and a rotation member for rotating the movable mounting table so that the buffer blade is moved to the standby position and the use position.

According to the exemplary embodiment of the present invention, wherein the rotation member may includes a vertical rotary shaft provided so that the buffer blade is rotated while maintaining a horizontal state when the buffer blade moves from the standby position to the use position.

According to the exemplary embodiment of the present invention, wherein the rotation member may includes a horizontal rotary shaft provided so that the buffer blade maintains a horizontal state in the use position, and so that the buffer blade is rotated in a vertical state when the buffer blade is moved from the use position to the standby position.

An exemplary embodiment of the present disclosure, a buffer unit that receives a substrate from a transfer unit and aligns the substrate when the substrate transferred by the transfer unit is misaligned in a substrate processing facility, the buffer unit may comprising: a buffer blade including alignment pins that align a substrate to a correct position; and a moving member for moving the buffer blade so that the buffer blade is moved to a standby position and a use position where the transfer unit is accessible.

According to the exemplary embodiment of the present invention, wherein the moving member may includes: a fixed mounting table on which the buffer blade is fixed; a movable mounting table on which the fixed mounting table is installed; and a horizontal driving unit for moving the movable mounting table in a horizontal direction.

According to the exemplary embodiment of the present invention, wherein the moving member further may includes a rotation member provided to allow the fixed mounting table to rotate on the movable mounting table.

According to the exemplary embodiment of the present invention, wherein the rotation member may includes: a hinge part including a rotary shaft connected to the fixed mounting table and a bearing installed on the rotary shaft and connected to the movable mounting table; a rotation driving unit for rotating the hinge part; and a foreign substance removing unit connected to the bearing to remove foreign substances by performing air intake on the bearing.

According to the exemplary embodiment of the present invention, wherein the horizontal driving unit may includes: a ball spline rotatably connected by an actuator; and a bellows installed to surround the ball spline and stretching in a longitudinal direction as the movable mounting table moves horizontally.

According to the exemplary embodiment of the present invention, wherein the moving member may includes: a fixed mounting table on which the buffer blade is fixed; a movable mounting table on which the fixed mounting table is installed; and a rotation member for rotating the movable mounting table so that the buffer blade is moved to the standby position and the use position.

According to the exemplary embodiment of the present invention, wherein the rotation member may includes a vertical rotary shaft provided so that the buffer blade is rotated while maintaining a horizontal state when the buffer blade moves from the standby position to the use position or a horizontal rotary shaft provided so that the buffer blade maintains a horizontal state in the use position, and so that the buffer blade is rotated in a vertical state when the buffer blade is moved from the use position to the standby position.

An exemplary embodiment of the present disclosure, a substrate processing facility comprising: a process module for processing a substrate; a transfer unit for transferring the substrate to the process module; and a buffer unit for receiving the substrate from the transfer unit and aligning the substrate when the alignment of the substrate transferred by the transfer unit is misaligned, wherein the buffer unit includes: a buffer blade including alignment pins that align a substrate to a correct position; and a moving member for moving the buffer blade so that the buffer blade is moved to a standby position and a use position where the transfer unit is accessible, the moving member includes: a fixed mounting table on which the buffer blade is fixed; a movable mounting table on which the fixed mounting table is installed; a horizontal driving unit for moving the movable mounting table in a horizontal direction; a rotation member provided so that the fixed mounting table is rotatable on the movable mounting table, the horizontal driving unit includes: a ball spline rotatably connected by an actuator; and a bellows installed to surround the ball spline and stretching in a longitudinal direction as the moving mounting table moves horizontally, and the rotation member includes: a hinge part including a rotary shaft connected to the fixed mounting table and a bearing installed on the rotary shaft and connected to the movable mounting table; and a rotation driving unit for rotating the hinge part.

According to the exemplary embodiment of the present invention, wherein the rotation member further may includes a foreign substance removing unit connected to the bearing to remove foreign substances by performing air intake on the bearing, and the foreign substance removing unit includes: an intake port installed on the bearing; and a suction line connected to the intake port.

According to the exemplary embodiment of the present invention, the alignment buffer unit may shorten an alignment time by reducing a transfer section of the main transfer unit by moving and disposing the buffer blade close to the main transfer unit when a substrate is aligned.

According to the exemplary embodiment of the present invention, the alignment buffer unit may position the buffer blade close to the sidewall of the facility by adopting the buffer blade movement method, thereby shortening maintenance time and simplifying maintenance work.

According to the exemplary embodiment of the present invention, particle contamination may be prevented by adopting the particle shielding function of the driving unit of the alignment buffer unit.

Effects of the present disclosure are not limited to those described above and effects not stated above will be clearly understood to those skilled in the art from the specification and the accompanying drawings

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIGS. 1 and 2 are plan view schematically illustrating a substrate processing facility according to an exemplary embodiment of the present invention.

FIG. 3 is a perspective view of the alignment buffer unit illustrated in FIG. 1.

FIGS. 4 and 5 are a plan view and a side view of the alignment buffer unit illustrated in FIG. 3, respectively.

FIG. 6 is a diagram of a fixed mounting table in which a buffer blade is installed view from the front.

FIG. 7 is a diagram illustrating a first modified example of the alignment buffer unit.

FIGS. 8 and 9 are diagrams illustrating a rotation member illustrated in FIG. 7.

FIG. 10 is a diagram illustrating a state in which the fixed mounting table is rotated.

FIG. 11 is a diagram illustrating a second modified example of the alignment buffer unit.

FIGS. 12A and 12B are diagrams illustrating a third modified example of the alignment buffer unit.

FIGS. 13A and 13B are diagrams illustrating a fourth modified example of the alignment buffer unit.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

In the present exemplary embodiment, a wafer is described as an example as an object to be processed. However, the technical idea of the present invention may be applied to devices used for processing other types of substrates other than wafers as objects to be processed.

Hereinafter, an exemplary embodiment of the present invention will be described with reference to the accompanying drawings.

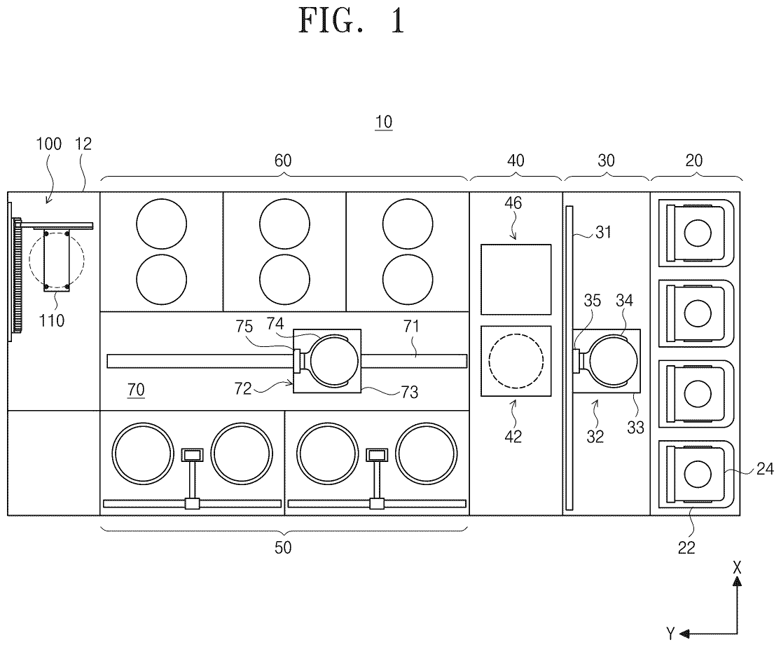

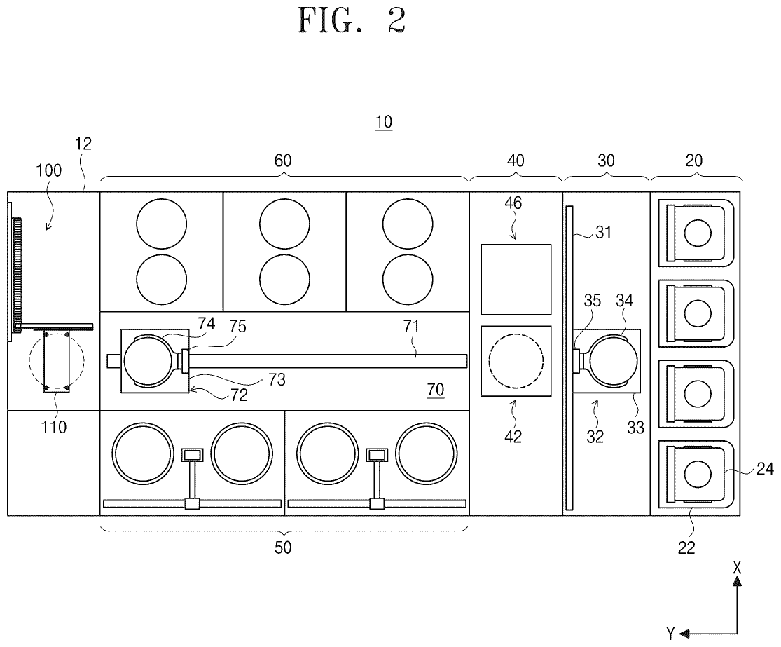

FIGS. 1 and 2 are top plan views schematically illustrating a substrate processing facility according to an exemplary embodiment of the present invention.

Referring to FIGS. 1 and 2, a substrate processing facility 10 may include a load port 20 for loading and unloading substrates, such as wafers, an index module 30, and a process module disposed on one side of the index module 30 and sequentially performing semiconductor processes on the wafers. The load port 20, the index module 30, and the process module may be disposed in one direction (Y direction). The process module may include a buffer chamber 40, a first process chamber 50, a second process chamber 60, a transfer chamber 70, and an alignment buffer unit 100.

In example exemplary embodiments, the substrate processing facility 10 may perform a semiconductor process, such as a coating process and a developing process, on the substrate. For example, the first process chamber 50 may perform a coating process for applying a photoresist film on the substrate and a developing process for developing the photoresist film exposed on the substrate, and the second process chamber 60 may perform a baking process for heating or cooling the applied photoresist film.

As illustrated in FIG. 1, the load port 20 may include a support plate 22 for supporting a wafer carrier (Front Opening Unified Pod (FOUP)) 24 in which a plurality of wafers W is accommodated. The load port 20 is a part in or from which a substrate is loaded or unloaded, and a plurality of support plates 24 may be disposed in the X direction in the load port 20.

The index module 30 may include an indexer robot 32 that is movable along an index rail 31 extending in the X direction within a frame. The indexer robot 32 may transfer the wafer between the wafer carrier 24 on the support plate 22 and the process module. The indexer robot 32 may include a base 33, a robot hand 34, and a vertical guide 35. The base 33 may be installed to be movable in the X direction along the index rail 32, the vertical guide 35 may be extended in the vertical direction on the base 33, and the robot hand 34 may be installed to be movable in the vertical direction along the vertical guide 35.

The process module may be disposed on one side of the index module 30. The buffer chamber 40 may be disposed on one side of the frame of the index module 30. The buffer chamber 40 may include a plurality of buffers 42 for temporarily storing a plurality of wafers, respectively. The buffer chamber 40 is provided for substrate transfer between the index robot and the transfer robot. A plurality of buffers 42 may be vertically spaced apart from each other. The buffer 42 may include a support plate 44 for supporting the wafer.

The buffer chamber 40 may further include a buffer robot 46 for transferring the substrate between the buffers 42. Although not illustrated, the buffer robot 46 may include a robot hand and a vertical guide. The vertical guide may extend in the vertical direction on the base, and the robot hand may be installed to be movable in the vertical direction along the vertical guide.

The transfer chamber 70 may extend from the buffer chamber 40 in a direction parallel to the Y direction. First process chambers 50 may be disposed on one side of the transfer chamber 70. Second process chambers 60 may be disposed on the other side of the transfer chamber 70. The first process chambers 50 may be disposed along the Y direction. The second process chambers 60 may be disposed along the Y direction. The first process chambers 50 may each include a plurality of coating devices or developing devices stacked in multiple stages in a vertical direction. The second process chambers 60 may each include a plurality of heat treating devices stacked in multiple stages in a vertical direction.

The buffer chamber 40 may provide a space in which a wafer transferred from the index module 30 to the first process chamber 50 and a wafer transferred from the second process chamber 60 to the index module 30 temporarily remain. A coating process of a wafer may be performed in the first process chamber 50. In the first process chamber 50, a coating process of applying a photoresist on a wafer may be performed. In the second process chamber 60, a heat treatment process, such as a baking process, may be performed on the wafer on which the coating process has been performed.

The transfer chamber 70 having a main transfer unit 72 for transferring a wafer may be provided between the first process chamber 50 and the second process chamber 60. The main transfer unit 72 may transfer a wafer while moving along the transfer rail 71 extending in the Y direction. The main transfer unit 72 may include a base 73, a robot hand 74, and a vertical guide 75. The base 73 may be installed to be movable in the Y direction along the transfer rail 71, the vertical guide 75 may extend in the vertical direction on the base 73, and the robot hand 74 may be installed to be movable in the vertical direction along the vertical guide 75.

The main transfer unit 72 may transfer the wafer placed on the buffer chamber 40 to the first process chamber 50. The main transfer unit 72 may transfer the wafer on which the coating process has been performed in the first process chamber 50 to the second process chamber 60. The main transfer unit 72 may transfer the wafer W on which the heat treatment process has been performed in the second process chamber 60 to the buffer chamber 40.

In example exemplary embodiments, a plurality of first process chambers 50 may be arranged in the Y direction. The types of photoresists used in each of the first process chambers 50 may be different from each other. As an example, a chemical amplification resist may be used as the photoresist. The first process chamber 50 may include a photoresist coating apparatus for performing a coating process of applying a photosensitive solution, such as a photoresist, on a wafer. The first process chamber 50 may be provided as a coating device for applying a photoresist on a wafer.

A plurality of second process chambers 60 may be arranged in the Y direction. The second process chamber 60 may heat-treat a wafer. For example, the second process chambers 60 may perform a pre-bake process of removing organic matter or moisture on the surface of the wafer by heating the wafer to a predetermined temperature before applying the photoresist, or a soft bake process performed after applying the photoresist on the wafer, and may perform a cooling process of cooling the wafer after each heating process. The second process chamber 60 may include a cooling plate 310 and a heating plate 210. The cooling plate 310 may be provided with a cooling device, such as cooling water or a thermoelectric element. In addition, the heating plate 210 may be provided with a heating device, such as a heating wire or a thermoelectric element. The second process chamber 60 may be provided as a heat treating device 62 of a substrate that heats or cools the applied photoresist film.

An alignment buffer unit 100 may be provided at one side of the second process chamber 60. The alignment buffer unit 100 is a unit for receiving a substrate from the main transfer unit 72 and positioning the substrate at the correct position when the alignment of the substrate transferred by the main transfer unit 72 is distorted in the substrate processing facility 10. The buffer blade 110 of the alignment buffer unit 100 may be provided to be movable between a standby position and a use position. The standby position of the buffer blade 110 is illustrated in FIG. 1, and the use position of the buffer blade 110 is illustrated in FIG. 2. The standby position is a position where the buffer blade 110 stands by in a state in which the substrate alignment is not required, and is located adjacent to a facility sidewall 12 to facilitate equipment maintenance. The use position is a position where the main transfer unit 72 is accessible when the substrate alignment is required, and the buffer blade 110 is located in a straight line with the transfer chamber.

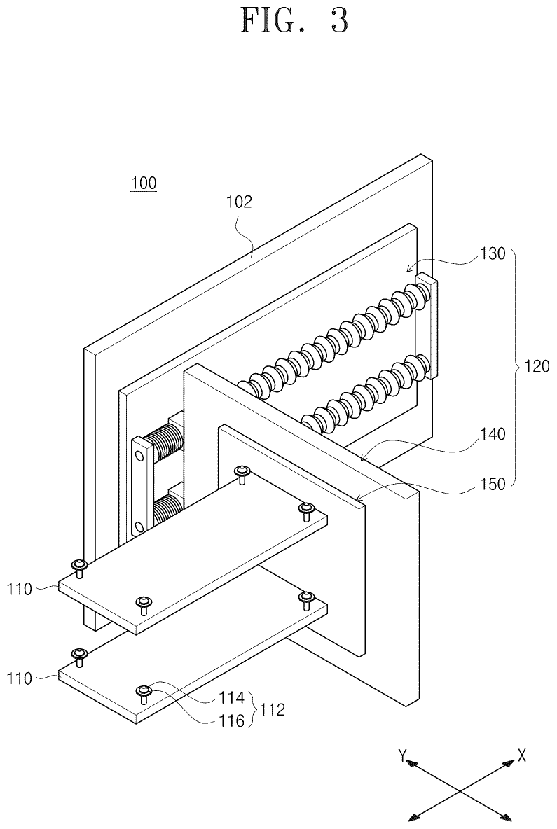

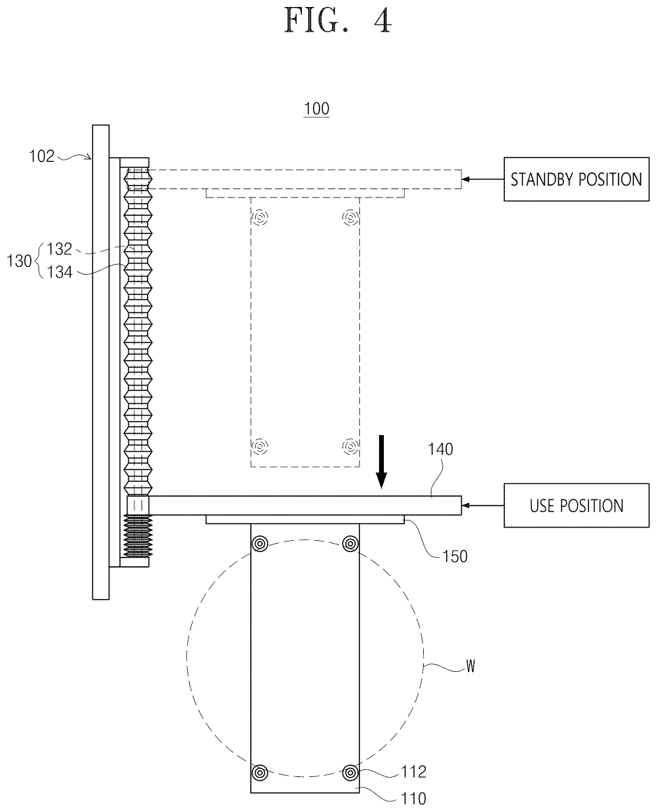

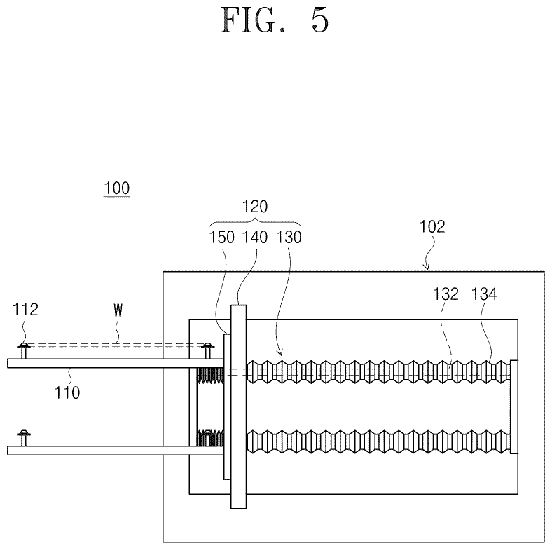

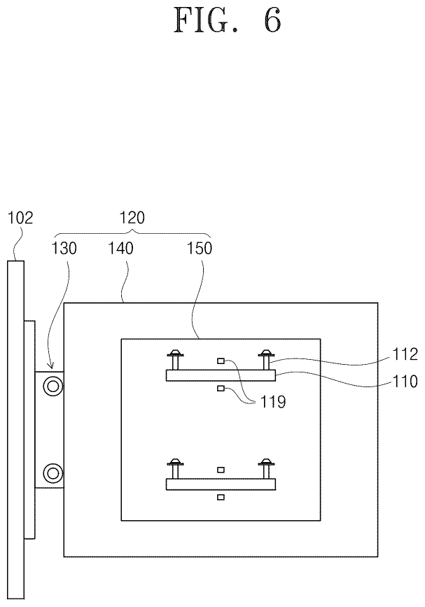

FIG. 3 is a perspective view of the alignment buffer unit illustrated in FIG. 1, FIGS. 4 and 5 are a plan view and a side view of the alignment buffer unit illustrated in FIG. 3, respectively, and FIG. 6 is a diagram of a fixed mounting table in which the buffer blade is installed viewed from the front.

Referring to FIGS. 3 to 6, the alignment buffer unit 100 may include a main frame 102, a moving member 120, and the buffer blade 110.

The buffer blade 110 has alignment pins 112 configured to align the substrate to the correct position. The alignment pins 112 may include an inclined portion 114 having a conical or truncated shape, and a support portion 116 on which the substrate lowered along the inclined portion 114 is seated. Although the alignment buffer unit 100 is illustrated to have two buffer blades 110, the present invention is not limited thereto. Among the two buffer blades, the upper end buffer blade is used for substrate alignment, and an Auto Bowl Cleaning (ABC) jig used for bowl cleaning of the first process chamber 50 may be stored in the lower end buffer blade.

The buffer blade 110 may be installed on the fixed mounting table 150. The fixed mounting table 150 may be provided with a substrate detection sensor (light receiving unit and light emitting unit) 119 for checking whether a substrate is present in the buffer blade 110. The horizontality of the buffer blade 110 may be adjusted by a level bolt.

The buffer blade 110 may be moved by the moving member 120 to the standby position and the use position where the transfer unit is accessible. The moving member 120 may include a horizontal driving unit 130, a movable mounting table 140, and the fixed mounting table 150. The fixed mounting table 150 may be installed in the movable mounting table 140.

The horizontal driving unit 130 may be installed on the main frame 102 in the X-axis direction. The horizontal driving unit 130 may include a linear driving module 132 and a bellows 134 for moving the movable mounting table 140 in the X-axis direction. For example, the linear driving module 132 may include a ball spline rotatably connected by an actuator. The bellows 134 may be installed to surround the linear driving module 132. The bellows 162 may be stretched in a longitudinal direction as the movable mounting table moves. As such, the horizontal driving unit 160 may shield particles generated when the linear driving module 132 is driven by the bellows 162 to prevent contamination of the substrate processing facility.

The buffer blade of the alignment buffer unit 100 moves to the non-used section (standby position) during the maintenance, and moves to the use position when the substrate alignment is required, and the alignment buffer unit may include a position sensor and a position determining pin that detect a movement to the standby position and the movement to the use position which are not illustrated.

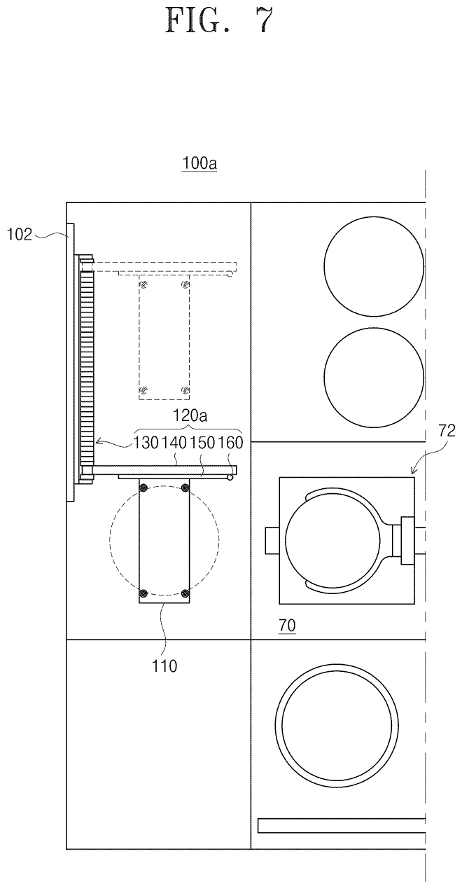

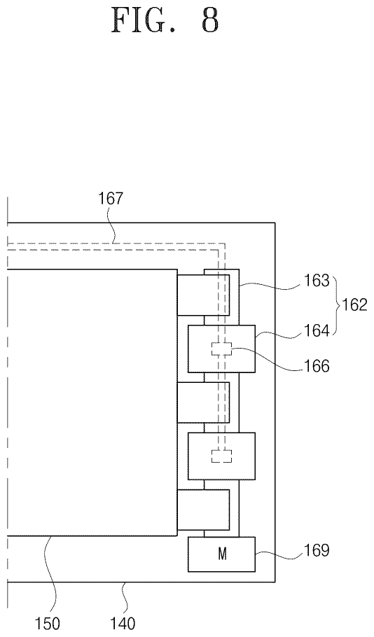

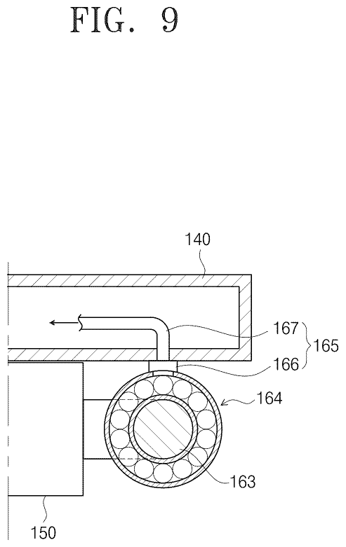

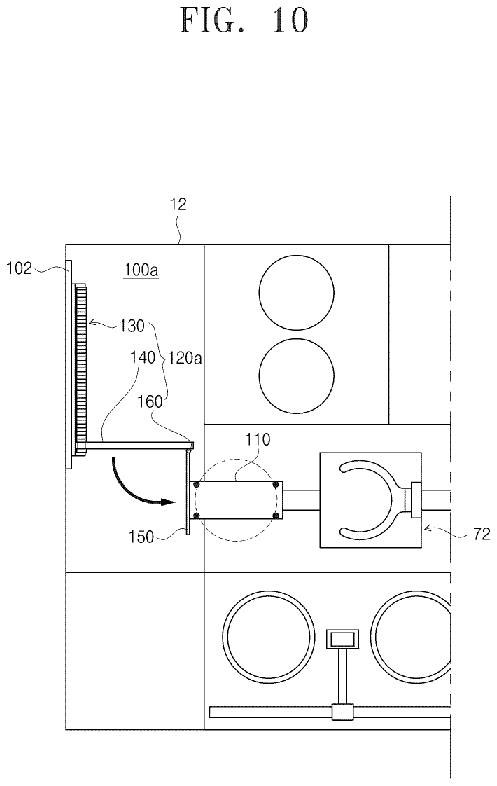

FIG. 7 is a diagram illustrating a first modified example of the alignment buffer unit, and FIGS. 8 and 9 are diagrams illustrating a rotation member illustrated in FIG. 7, and FIG. 10 is a diagram illustrating a state in which the fixed mounting table is rotated.

An alignment buffer unit 100a illustrated in FIGS. 7 to 10 includes a main frame 102, a moving member 120a, and a buffer blade 110, which are provided with a configuration and function substantially similar to the main frame 102, the moving member 120, and the buffer blade 110 of the alignment buffer unit illustrated in FIGS. 3 to 6, and thus a modified example will be described below, focusing on differences from the present exemplary embodiment.

In the present modified exemplary embodiment, the moving member 120a further includes a rotation member 160 provided to allow the fixed mounting table 150 to rotate on the movable mounting table 140. The position of the buffer blade 110 may be adjusted by the rotation member 160 to a position where the main transfer robot 72 is easily accessible. The rotation member 160 may include a hinge part 162 and a rotation driving part 169. The hinge part 162 may include a rotary shaft 163 connected to the fixed mounting table 150, and a bearing 164 installed on the rotary shaft 163 and connected to the movable mounting table 140. The rotation driving part 169 may be an actuator for rotating the rotary shaft 163 of the hinge part 162.

As described above, in the present modified example, when it is desired to change the position of the straight section to reduce the transfer path of the main transfer unit 72, the position of the buffer blade 110 may be changed to a position closer to the main transfer unit 72 through the operation of the rotation member 160 within a range in which substrate loading/unloading is possible. As illustrated in FIG. 10, the buffer blade 110 enters the region of the transfer chamber 70, so that the main transfer unit 72 may easily access the buffer blade 110, and a moving distance for loading/unloading the substrate onto the buffer blade 110 may be reduced.

Meanwhile, a foreign substance removing unit 165 may be provided in the rotation member 160. The foreign substance removing unit 165 may be connected to the bearing 164 to remove foreign substances by performing air suction with respect to the inside of the bearing 164. The foreign substance removing unit 165 may include an intake port 166 installed in the bearing 164, and a suction line 167 connected to the intake port 166. The suction line 167 may be installed through the inside of the movable mounting table 140. Although not illustrated, a space between the intake port 166 and the bearing 164 may be shielded by a method, such as O-ring or gasket seal fitting.

As described above, the moving member 120a suctions particles generated by friction between the rotary shaft of the rotation member 160 and the bearing, thereby minimizing surrounding contamination caused by particles.

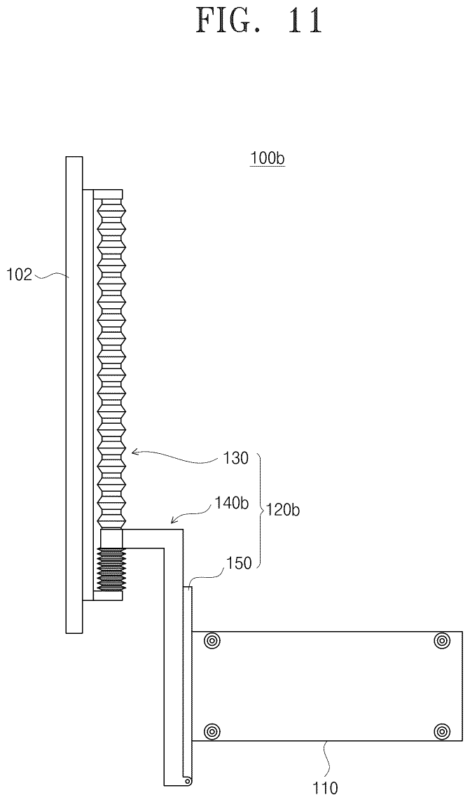

FIG. 11 is a diagram illustrating a second modified example of the alignment buffer unit.

An alignment buffer unit 100b illustrated in FIG. 11 includes a main frame 102, a moving member 120b, and a buffer blade 110, which are provided with a configuration and function substantially similar to the main frame 102, the moving member 120, and the buffer blade 110 of the alignment buffer unit illustrated in FIGS. 3 to 6, and thus a modified example will be described below, focusing on differences from the present exemplary embodiment.

In the present modified example, the moving member 120b differs in that the structure of the movable mounting table 140b is changed so that the buffer blade 110 faces the transfer chamber 70 where the main transfer unit 72 is located.

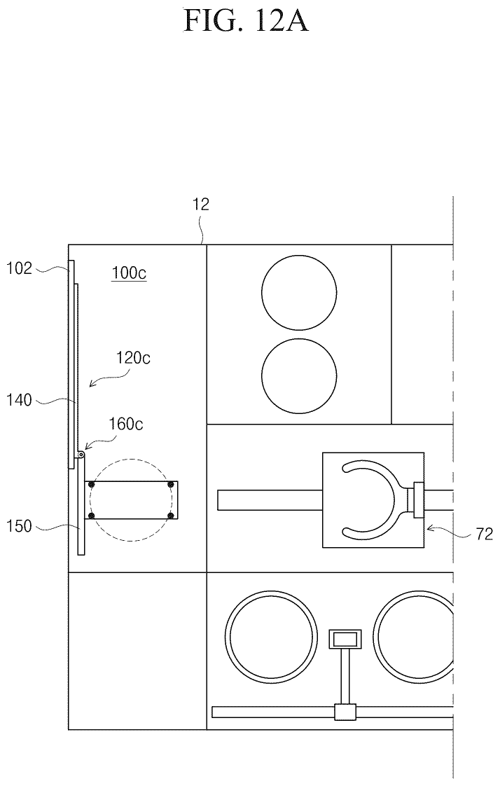

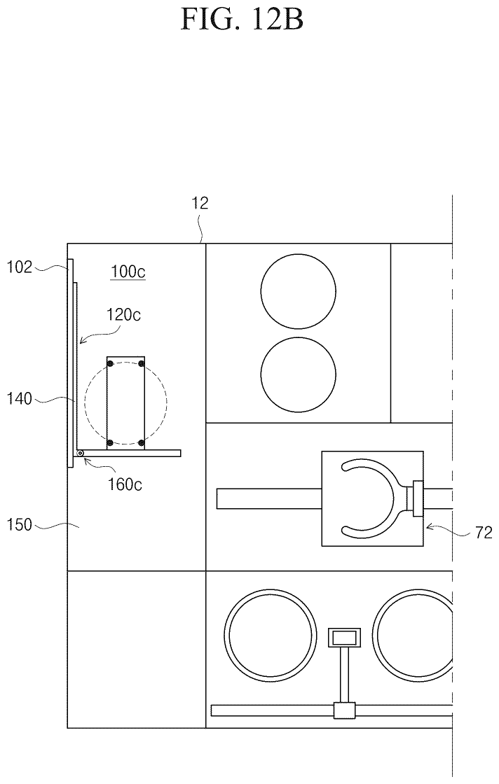

FIGS. 12A and 12B are diagrams illustrating a third modified example of the alignment buffer unit.

An alignment buffer unit 100c illustrated in FIGS. 12A and 12B includes a main frame 102, a moving member 120c, and a buffer blade 110, which are provided with a configuration and function substantially similar to the main frame 102, the moving member 120, the buffer blade 110, and the rotation member 160 of the alignment buffer unit illustrated in FIGS. 7 to 10, and thus a modified example will be described below, focusing on differences from the present exemplary embodiment.

In the present modified example, the moving member 120c may omit the horizontal driving unit and move the buffer blade 110 to the use position and the standby position by using the rotation member 160c. That is, the buffer blade 110 may be rotated by the rotation member 160c to a position (use position) at which the main transfer unit 72 is accessible (see FIG. 12A). Further, during maintenance, the buffer blade 110 may be rotated by the rotation member 160c to a position (standby position) facing the facility sidewall 12 (see FIG. 12B).

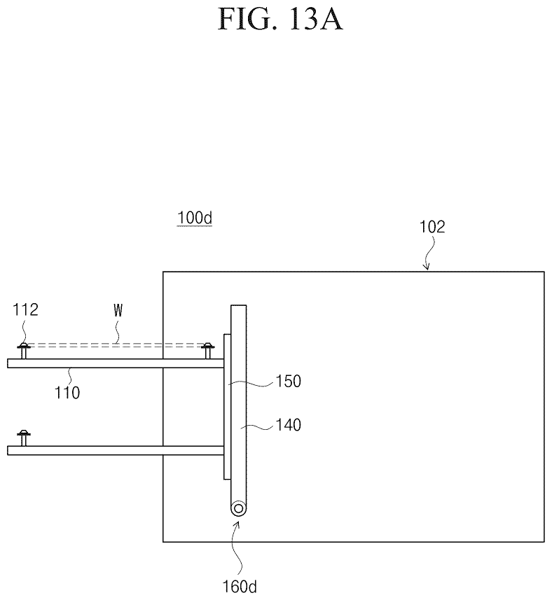

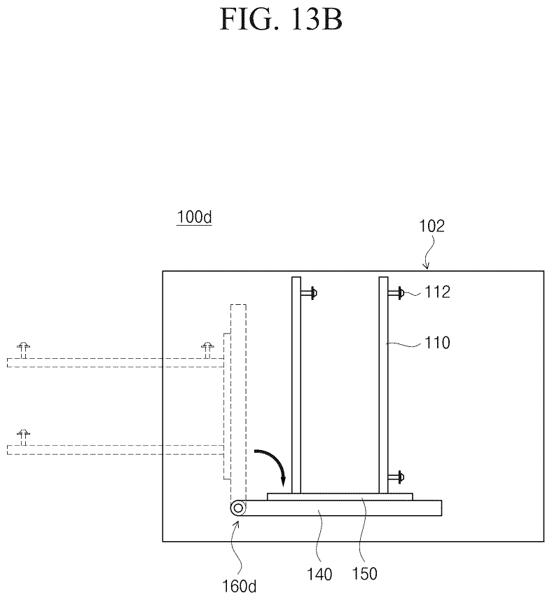

FIGS. 13A and 13B are diagrams illustrating a fourth modified example of the alignment buffer unit.

An alignment buffer unit 100d illustrated in FIGS. 13A and 13B includes a main frame 102, a moving member 120c, a buffer blade 110, and a rotation member 160d, which are provided with a configuration and function substantially similar to the main frame 102, the moving member 120, the buffer blade 110, and the rotation member 160c of the alignment buffer unit illustrated in FIG. 12A, and thus a modified example will be described below, focusing on differences from the present exemplary embodiment.

In the present modified example, the rotation axis of the rotation member 160d is horizontally provided in the Y-axis direction. The rotation member 160d is installed on the movable mounting table 140 and the main frame 102. The movable mounting table 140 may be rotated from a vertical state to a horizontal state by the rotation member 160d. The buffer blade 110 is mounted on the movable mounting table 140. The buffer blade 110 may be moved to a use position and a standby position by the rotation member 160d. The use position of the buffer blade 110 is a position where the main transfer unit 72 is accessible by the rotation member 160d (see FIG. 13A), and the standby position of the buffer blade 110 is a position vertically erected by the rotation member 160d (see FIG. 13B).

The specification described above provides examples of the present disclosure. Further, the description provides exemplary embodiments of the present disclosure and the present disclosure may be used in other various combinations, changes, and environments. That is, the present disclosure may be changed or modified within the scope of the present disclosure described herein, within a range equivalent to the description, and/or within the knowledge or technology in the related art. The embodiment shows an optimum state for achieving the spirit of the present disclosure and may be changed in various ways for the detailed application fields and use of the present disclosure. Therefore, the detailed description of the present disclosure is not intended to limit the present disclosure in the embodiment. Further, the claims should be construed as including other embodiments.

What is claimed is:

1. A substrate processing facility comprising:
a process module for processing a substrate;
a buffer unit having a buffer blade on which the substrate is placed; and
a transfer unit for transferring the substrate between the process module and the buffer unit,
wherein the buffer unit includes a moving member for moving the buffer blade so that the buffer blade is moved to a standby position and a use position where the transfer unit is accessible.

2. The substrate processing facility of claim 1, wherein the moving member includes:
a fixed mounting table on which the buffer blade is fixed;
a movable mounting table on which the fixed mounting table is installed; and
a horizontal driving unit for moving the movable mounting table in a horizontal direction.

3. The substrate processing facility of claim 2, wherein the moving member further includes a rotation member provided to allow the fixed mounting table to rotate on the movable mounting table.

4. The substrate processing facility of claim 3, wherein the rotation member includes:
a hinge part including a rotary shaft connected to the fixed mounting table and a bearing installed on the rotary shaft and connected to the movable mounting table; and
a rotation driving unit for rotating the hinge part.

5. The substrate processing facility of claim 4, further comprising:
a foreign substance removing unit connected to the bearing to remove foreign substances by performing air intake on the bearing.

6. The substrate processing facility of claim 5, wherein the foreign substance removing unit includes:
an intake port installed on the bearing; and
a suction line connected to the intake port.

7. The substrate processing facility of claim 2, wherein the horizontal driving unit includes:
a ball spline rotatably connected by an actuator; and
a bellows that is installed to surround the ball spline and is stretched in a longitudinal direction as the movable mounting table moves horizontally.

8. The substrate processing facility of claim 3, wherein the buffer blade is positioned in a transfer region where the transfer unit is located by a rotation operation of the rotation member.

9. The substrate processing facility of claim 1, wherein the moving member includes:
a fixed mounting table on which the buffer blade is fixed;
a movable mounting table on which the fixed mounting table is installed; and
a rotation member for rotating the movable mounting table so that the buffer blade is moved to the standby position and the use position.

10. The substrate processing facility of claim 9, wherein the rotation member includes a vertical rotary shaft provided so that the buffer blade is rotated while maintaining a horizontal state when the buffer blade moves from the standby position to the use position.

11. The substrate processing facility of claim 9, wherein the rotation member includes a horizontal rotary shaft provided so that the buffer blade maintains a horizontal state in the use position, and so that the buffer blade is rotated in a vertical state when the buffer blade is moved from the use position to the standby position.

12. A buffer unit that receives a substrate from a transfer unit and aligns the substrate when the substrate transferred by the transfer unit is misaligned in a substrate processing facility, the buffer unit comprising:
a buffer blade including alignment pins that align a substrate to a correct position; and
a moving member for moving the buffer blade so that the buffer blade is moved to a standby position and a use position where the transfer unit is accessible.

13. The buffer unit of claim 12, wherein the moving member includes:
a fixed mounting table on which the buffer blade is fixed;
a movable mounting table on which the fixed mounting table is installed; and
a horizontal driving unit for moving the movable mounting table in a horizontal direction.

14. The buffer unit of claim 13, wherein the moving member further includes a rotation member provided to allow the fixed mounting table to rotate on the movable mounting table.

15. The buffer unit of claim 14, wherein the rotation member includes:
a hinge part including a rotary shaft connected to the fixed mounting table and a bearing installed on the rotary shaft and connected to the movable mounting table;
a rotation driving unit for rotating the hinge part; and
a foreign substance removing unit connected to the bearing to remove foreign substances by performing air intake on the bearing.

16. The buffer unit of claim 14, wherein the horizontal driving unit includes:
a ball spline rotatably connected by an actuator; and
a bellows installed to surround the ball spline and stretching in a longitudinal direction as the movable mounting table moves horizontally.

17. The buffer unit of claim 12, wherein the moving member includes:
a fixed mounting table on which the buffer blade is fixed;
a movable mounting table on which the fixed mounting table is installed; and
a rotation member for rotating the movable mounting table so that the buffer blade is moved to the standby position and the use position.

18. The buffer unit of claim 17, wherein the rotation member includes a vertical rotary shaft provided so that the buffer blade is rotated while maintaining a horizontal state when the buffer blade moves from the standby position to the use position or a horizontal rotary shaft provided so that the buffer blade maintains a horizontal state in the use position, and so that the buffer blade is rotated in a vertical state when the buffer blade is moved from the use position to the standby position.

19. A substrate processing facility comprising:
a process module for processing a substrate;
a transfer unit for transferring the substrate to the process module; and
a buffer unit for receiving the substrate from the transfer unit and aligning the substrate when the alignment of the substrate transferred by the transfer unit is misaligned,
wherein the buffer unit includes:
a buffer blade including alignment pins that align a substrate to a correct position; and
a moving member for moving the buffer blade so that the buffer blade is moved to a standby position and a use position where the transfer unit is accessible,
the moving member includes:
a fixed mounting table on which the buffer blade is fixed;
a movable mounting table on which the fixed mounting table is installed;
a horizontal driving unit for moving the movable mounting table in a horizontal direction;
a rotation member provided so that the fixed mounting table is rotatable on the movable mounting table,
the horizontal driving unit includes:
a ball spline rotatably connected by an actuator; and
a bellows installed to surround the ball spline and stretching in a longitudinal direction as the moving mounting table moves horizontally, and
the rotation member includes:
a hinge part including a rotary shaft connected to the fixed mounting table and a bearing installed on the rotary shaft and connected to the movable mounting table; and
a rotation driving unit for rotating the hinge part.

20. The substrate processing facility of claim 19, wherein the rotation member further includes a foreign substance removing unit connected to the bearing to remove foreign substances by performing air intake on the bearing, and
the foreign substance removing unit includes:
an intake port installed on the bearing; and
a suction line connected to the intake port.
